(19) United States
(12) Patent Application Publication
(10) Pub. No.: US 2016/0056048 A1
(43) Pub. Date: Feb. 25, 2016

(54) METHOD OF MANUFACTURING SEMICONDUCTOR DEVICE AND SEMICONDUCTOR DEVICE

(71) Applicant: KABUSHIKI KAISHA TOSHIBA, Minato-ku (JP)

(72) Inventor: Shingo HONDA, Yokkaichi (JP)

(73) Assignee: KABUSHIKI KAISHA TOSHIBA, Minato-ku (JP)

(21) Appl. No.: 14/618,016

(22) Filed: Feb. 10, 2015

(30) Foreign Application Priority Data
Aug. 22, 2014 (JP) 2014-169397

(51) Int. Cl. H01L 21/308; H01L 21/3065; H01L 21/768; H01L 23/48

(52) U.S. Cl. CPC H01L 21/3086; H01L 23/481; H01L 21/3065; H01L 21/3081; H01L 21/76898

(57) ABSTRACT

A method of manufacturing a semiconductor device includes forming a first layer comprising an organic film above a work layer; forming a second layer comprising an inorganic film above the organic film; forming a third layer above the second layer; and forming an opening pattern into the third layer. The method further includes etching the second layer, the first layer, and the work layer using the third layer as a mask, the etching progressing obliquely through the first layer to form a slope in the first layer. The method still further includes removing the first layer to cause the second layer to be disposed in direct contact with the work layer to thereby form a step portion.

### CROSS-REFERENCE TO RELATED APPLICATION(S)

This application is based upon and claims the benefit of priority from Japanese Patent Application No. 2014-169397, filed on, Aug. 22, 2014 the entire contents of which are incorporated herein by reference.

### FIELD

Embodiments disclosed herein generally relate to a method of manufacturing semiconductor device and semiconductor device.

### BACKGROUND

When simultaneously forming opening patterns having different depths into the semiconductor substrate, a film having selectivity to the etching is used as an underlying etch stopper. When etching high-aspect-ratio patterns, it is required to use high ion energy. Thus, when sufficient level of etch selectivity is obtained relative to the etch stopper, the inner diameter at the lower portion of the etched pattern tends to become small which may increase the contact resistance.

On the other hand, when the inner diameter at the lower portion of the pattern is increased to reduce the contact resistance, sufficient etch selectivity with respect to the underlying stopper cannot be obtained. This may cause the etching to progress through the stopper.

### BRIEF DESCRIPTION OF THE DRAWINGS

FIG. 1 pertains to a first embodiment and is one example of a cross-sectional view of a semiconductor device in one phase of a manufacturing process flow.

FIG. 2 is one example of a cross-sectional view of the semiconductor device in one phase of a manufacturing process flow.

FIG. 3 is one example of a cross-sectional view of the semiconductor device in one phase of a manufacturing process flow.

FIG. 4 is one example of a cross-sectional view of the semiconductor device in one phase of a manufacturing process flow.

FIG. 5 is one example of a cross-sectional view of the semiconductor device in one phase of a manufacturing process flow.

FIG. 6 is one example of a cross-sectional view of the semiconductor device in one phase of a manufacturing process flow.

FIG. 7 is one example of a cross-sectional view of the semiconductor device in one phase of a manufacturing process flow.

FIG. 8 is one example of a cross-sectional view of the semiconductor device in one phase of a manufacturing process flow.

FIG. 9 is one example of a cross-sectional view of the semiconductor device in one phase of a manufacturing process flow.

FIG. 10 is one example of a cross-sectional view of the semiconductor device in one phase of a manufacturing process flow.

FIG. 11 is one example of a cross-sectional view of the semiconductor device in one phase of a manufacturing process flow.

FIG. 12 is one example of a cross-sectional view of the semiconductor device in one phase of a manufacturing process flow.

FIG. 13 is one example of a cross-sectional view of the semiconductor device in one phase of a manufacturing process flow.

FIG. 14 is one example of a cross-sectional view of the semiconductor device in one phase of a manufacturing process flow.

FIG. 15 is one example of a cross-sectional view of the semiconductor device in one phase of a manufacturing process flow.

### DESCRIPTION

In one embodiment, a method of manufacturing a semiconductor device includes forming a first layer comprising an organic film above a work layer; forming a second layer comprising an inorganic film above the organic film; forming a third layer above the second layer; and forming an opening pattern into the third layer. The method further includes etching the second layer, the first layer, and the work layer using the third layer as a mask, the etching progressing obliquely through the first layer to form a slope in the first layer. The method still further includes removing the first layer to cause the second layer to be disposed in direct contact with the work layer to thereby form a step portion

In one embodiment, a semiconductor device includes a work layer; a plurality of step portions defined in an upper surface of the work layer; an inorganic film disposed in an outer side of the plurality of step portions defined in the upper surface of the work layer, the inorganic film having two step portions defined therein; and a plurality of holes extending into the plurality of step portions defined in the upper surface of the work layer and the two step portions defined in the inorganic film.

### EMBODIMENTS

Embodiments are described herein with reference to the accompanying drawings. Elements that are substantially identical across the embodiments are identified with identical reference symbols and may not be re-described. The drawings are schematic, and do not necessarily reflect the actual measurements of the features such as the correlation of thickness to planar dimensions and the ratio of thicknesses of each of the layers.

### First Embodiment

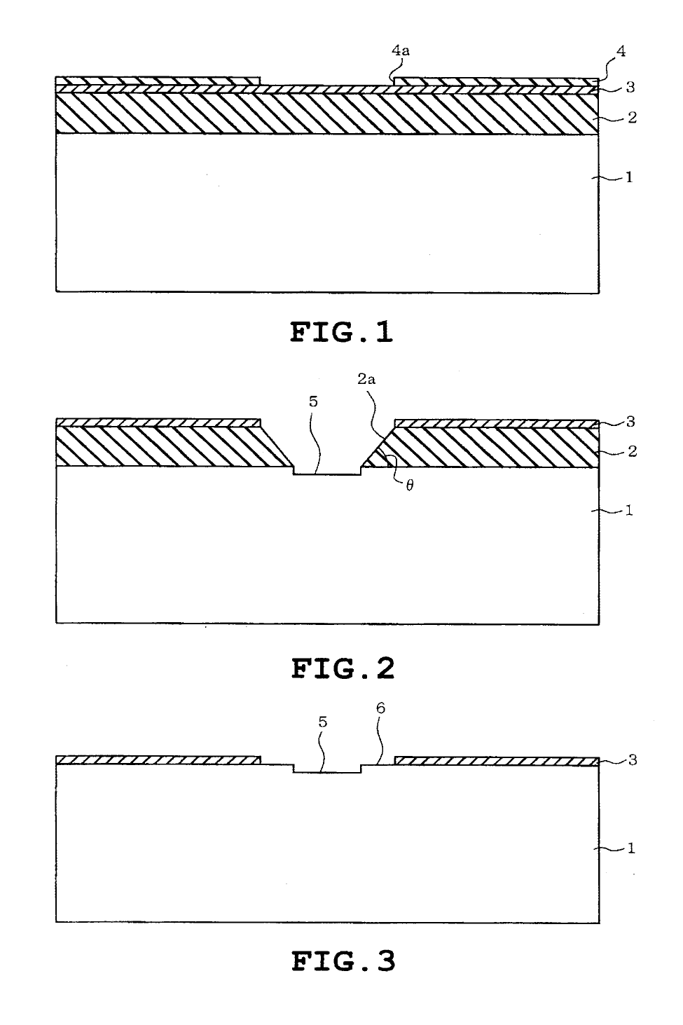

With reference to the accompanying drawings, a description will be given on a first embodiment. Referring first to FIG. 1, a SMAP (stacked mask process) structure is formed above semiconductor substrate 1. Semiconductor substrate 1 serves as a work layer being worked upon and may be formed of silicon (Si) for example.

The SMAP structure comprises coating-type resist layer 2, coating-type oxide film 3, and photoresist layer 4 formed one after another above semiconductor substrate 1. Coating-type resist layer 2 primarily comprises an SOC (spin on carbon) for example and serves as a first layer. Coating-type oxide film 3 comprises an SOG (spin on glass) for example and serves as a second layer. Photoresist layer 4 serves as a third layer. Photoresist layer 4 has opening 4a formed therethrough by lithography. As later described, opening 4a is used for forming stepped structures and serves as an opening pattern.

Next, as illustrated in FIG. 2, coating-type oxide film 3, coating-type resist layer 2, and semiconductor substrate 1 are etched for example by RIE (reactive ion etching) using photoresist layer 4 as a mask. Coating-type resist layer 2 is etched into a forward taper so that the width of the opening formed into coating-type resist layer 2 becomes smaller as the elevation becomes lower, in other words, towards the bottom. Stated differently, the etching progresses in an oblique profile. Slopes 2a defining the forward taper form inclination angle θ ranging from 60 degrees to 84 degrees. Recess 5 is formed into semiconductor substrate 1 by the etching.

Then, as illustrated in FIG. 3, coating-type resist layer 2 is removed for example by dry etching or, more specifically, by ashing. The ashing performed in the first embodiment is performed inside the RIE chamber. The ashing is performed under the following conditions. A process gas is used in which the concentration of oxygen gas occupies approximately 80% or more of the total gas content for example. Oxygen gas; a mixture of oxygen gas and nitrogen gas; a mixture of oxygen gas, argon gas, and nitrogen gas; or a mixture of oxygen gas and methane gas, etc. is preferably used as the process gas. The temperature of semiconductor substrate 1 is preferably specified to range from −10 degrees Celsius to 80 degrees Celsius. The temperature of semiconductor substrate 1 is elevated to range approximately from 100 degrees Celsius to 160 degrees Celsius while the ashing is ongoing by the thermal radiation from plasma. The removal of coating-type resist layer 2 causes coating-type oxide film 3 to be placed in direct contact with semiconductor substrate 1 and thereby form step portion 6.

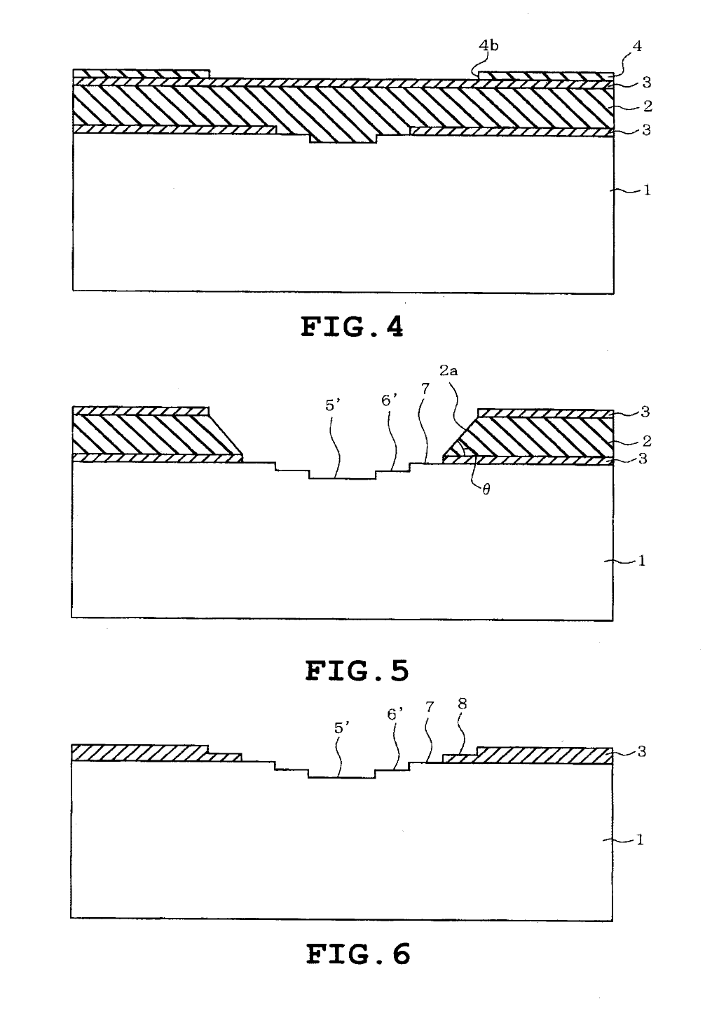

Referring next to FIG. 4, the SMAP structure is formed for the second time above coating-type oxide film 3 and semiconductor substrate 1. More specifically, coating-type resist layer 2 serving as an eleventh layer, coating-type oxide film 3 serving as a twenty first layer, and photoresist layer 4 serving as a thirty first layer are formed one after another above semiconductor substrate 1. Photoresist layer 4 has opening 4b formed therethrough by lithography. As later described, opening 4b is used for forming stepped structures and serves as an opening pattern.

Next, as illustrated in FIG. 5, coating-type oxide film 3, coating-type resist layer 2, and semiconductor substrate 1 are etched for example by RIE using photoresist layer 4 as a mask. Coating-type resist layer 2 is etched into a forward taper so that the width of the opening formed into coating-type resist layer 2 becomes smaller as the elevation becomes lower, in other words, towards the bottom. Slopes 2a defining the forward taper form inclination angle θ ranging from 60 degrees to 84 degrees for example. Recess 5′, step portion 6′ and step portion 7 are formed into semiconductor substrate 1 by the etching.

Then, as illustrated in FIG. 6, coating-type resist layer 2 is removed for example by dry etching or, more specifically, by ashing. The ashing performed in the first embodiment is performed inside the RIE chamber. The ashing is performed under the following conditions. A process gas is used in which the concentration of oxygen gas occupies approximately 80% or more of the total gas content for example. Oxygen gas; a mixture of oxygen gas and nitrogen gas; a mixture of oxygen gas, argon gas, and nitrogen gas; or a mixture of oxygen gas and methane gas, etc. is preferably used as the process gas. The temperature of semiconductor substrate 1 is preferably specified to range from −10 degrees Celsius to 80 degrees Celsius. The temperature of semiconductor substrate 1 is elevated to range approximately from 100 degrees Celsius to 160 degrees Celsius while the ashing is ongoing by the thermal radiation from plasma. The removal of coating-type resist layer 2 causes coating-type oxide film 3 to be placed in direct contact with semiconductor substrate 1 and thereby form step portion 8.

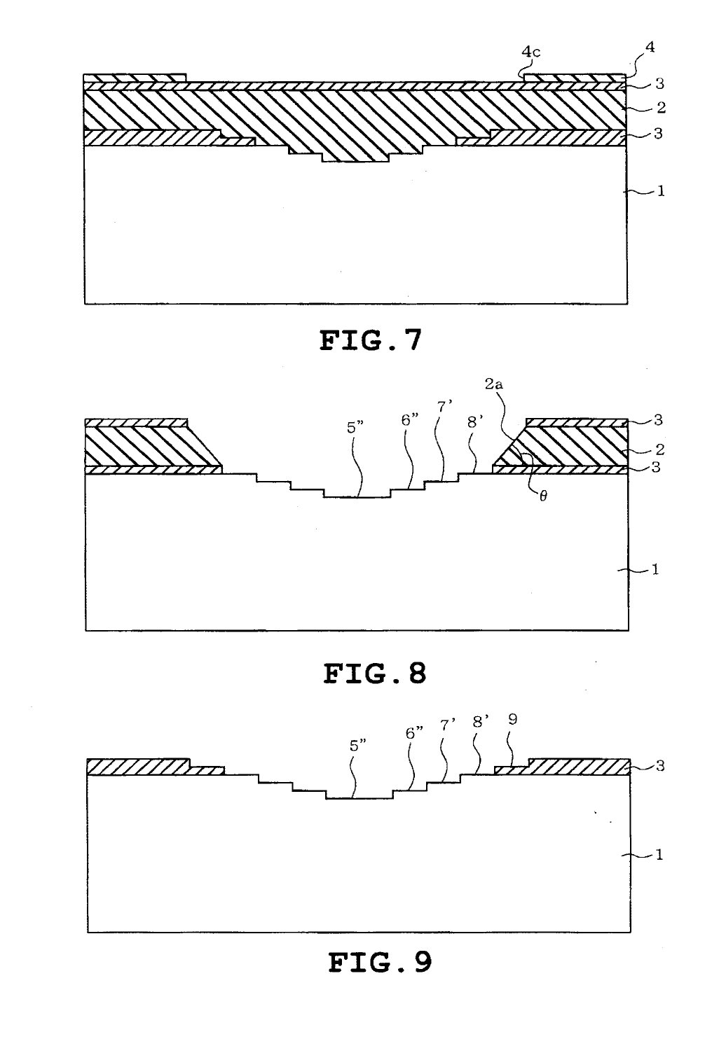

Referring next to FIG. 7, the SMAP structure is formed for the third time above coating-type oxide film 3 and semiconductor substrate 1. More specifically, coating-type resist layer 2 serving as an eleventh layer, coating-type oxide film 3 serving as a twenty first layer, and photoresist layer 4 serving as a thirty first layer are formed one after another above semiconductor substrate 1. Photoresist layer 4 has opening 4c formed therethrough by lithography. As later described, opening 4c is used for forming stepped structures and serves as an opening pattern.

Next, as illustrated in FIG. 8, coating-type oxide film 3, coating-type resist layer 2, and semiconductor substrate 1 are etched for example by RIE using photoresist layer 4 as a mask. Coating-type resist layer 2 is etched into a forward taper so that the width of the opening formed into coating-type resist layer 2 becomes smaller as the elevation becomes lower, in other words, towards the bottom. Slopes 2a defining the forward taper form inclination angle θ ranging from 60 degrees to 84 degrees. Recess 5″, step portion 6″, step portion 7′, and step portion 8′ are formed into semiconductor substrate 1 by the etching.

Then, as illustrated in FIG. 9, coating-type resist layer 2 is removed for example by dry etching or, more specifically, by ashing. The ashing performed in the process step illustrated in FIG. 6 is performed to remove coating-type resist layer 2. The removal of coating-type resist layer 2 causes coating-type oxide film 3 to be placed in direct contact with the existing coating-type oxide film 3 disposed above semiconductor substrate 1 and thereby form step portion 9. The process steps illustrated in FIGS. 7 to 9 may be repeated when further step portions need to be formed.

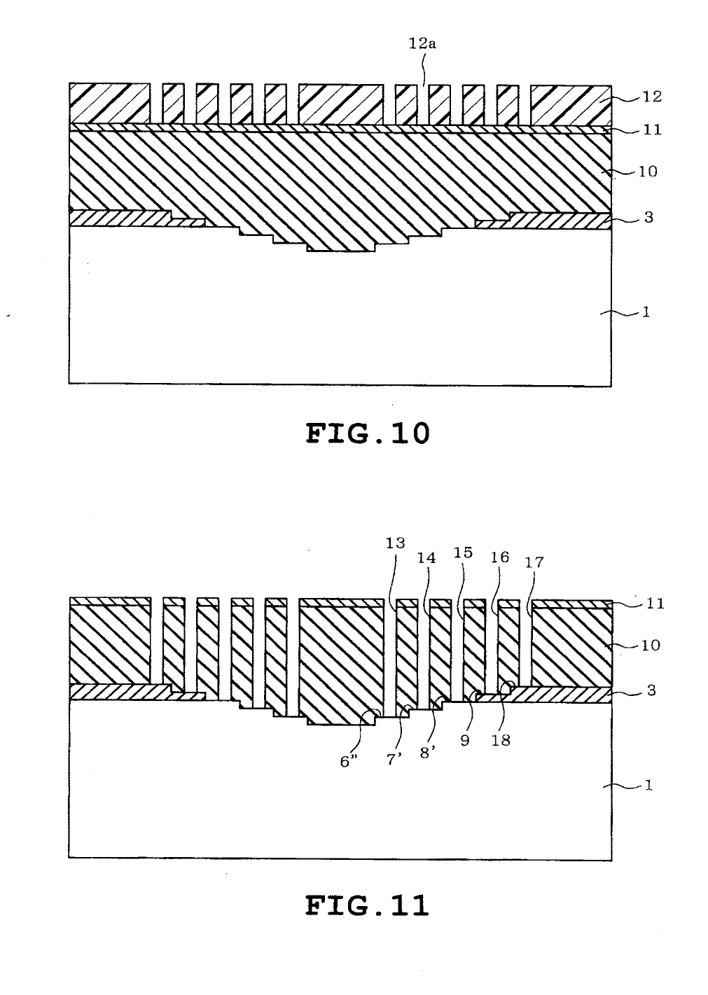

Then, as illustrated in FIG. 10, coating-type resist layer 10 is formed above semiconductor substrate 1 and coating-type oxide film 3. Coating-type resist layer 10 primarily comprises an SOC (spin on carbon) for example and serves as a fourth layer. Then, Coating-type oxide film 11 is formed above coating-type resist layer 10. Coating-type oxide film 11 comprises an SOG (spin on glass) for example and serves as a fifth layer. Then, photoresist layer 12 is formed above coating-type oxide film 11. Photoresist layer 12 serves as a sixth layer. Next, mask pattern 12a is formed through photoresist layer 12 using photolithography. Mask pattern 12a is used for forming a contact hole for example and serves as a hole pattern.

Then, as illustrated in FIG. 11, holes 13, 14, 15, 16 and 17 are formed by etching coating-type oxide film 11 and coating-type resist layer 10 by RIE for example using photoresist layer 12 as a mask. The process gas used in the RIE primarily comprises an oxygen gas and does not contain fluorine gas for example. Thus, etching of semiconductor substrate 1 and coating-type oxide film 3 is inhibited. More specifically, hole 13 is stopped at the upper surface of step portion 6″ of semiconductor substrate 1. Hole 14 is stopped at the upper surface of step portion 7′ of semiconductor substrate 1. Hole 15 is stopped at the upper surface of step portion 8′ of semiconductor substrate 1. Hole 16 is stopped at the upper surface of step portion 9 of coating-type oxide film 3. Hole 17 is stopped at the upper surface of step portion 18 of coating-type oxide film 3.

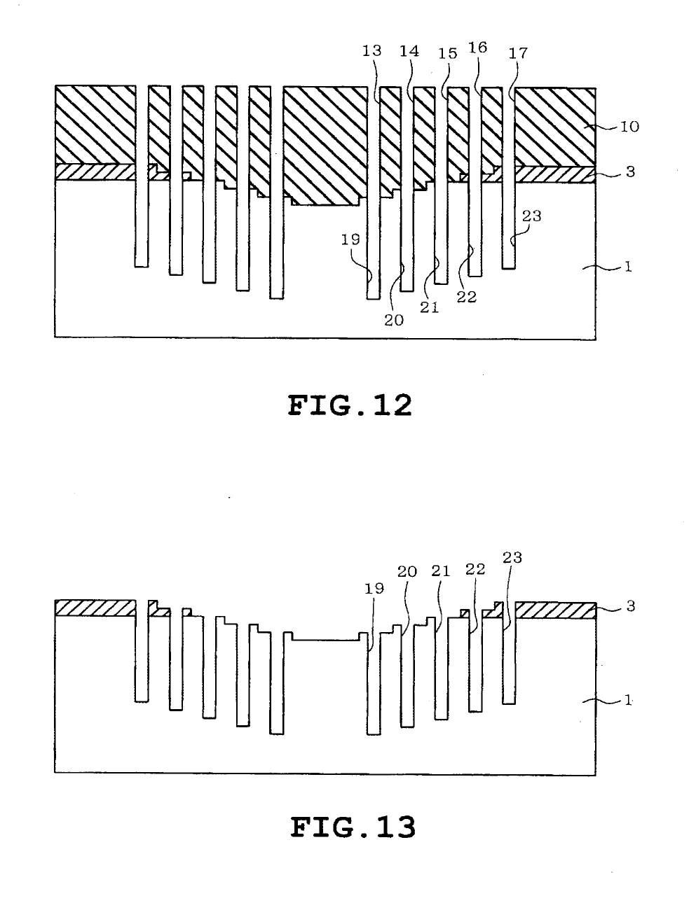

Next, as illustrated in FIG. 12, contact holes 19, 20, 21, 22, and 23 are formed by etching semiconductor substrate 1 and coating-type oxide film 3 using RIE for example. The process gas used in the RIE is a mixture of oxygen gas and gas primarily comprising CF, meaning that fluorine gas is contained. The etching progresses by the reaction of oxygen gas and C of CF-containing gas and thus, the etching of the lower layer resist, such as coating-type resist layer 10 in this example, does not progress aggressively and thus, remains substantially intact. Semiconductor substrate 1 and coating-type oxide film 3 are etched substantially at the same etch rate. Contact holes 19 to 23 having different depths are formed in the above described manner.

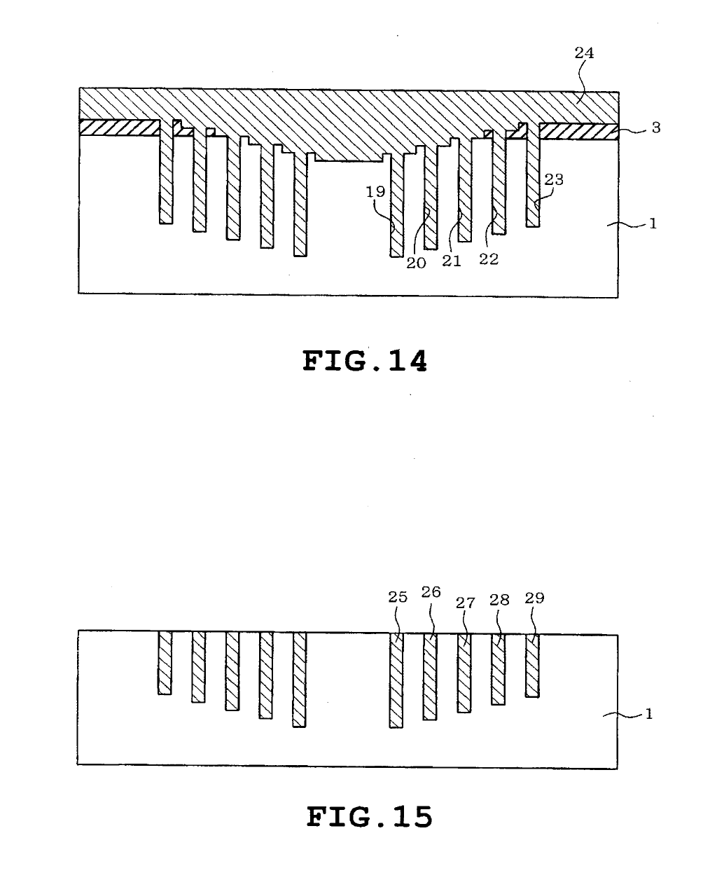

Thereafter, as illustrated in FIG. 13, coating-type resist layer 10 is removed for example by ashing. Then, as illustrated in FIG. 14, contact holes 19 to 23 are filled with metal material 24 serving as wirings. Tungsten (W) may be used for example as metal material 24. Then, as illustrated in FIG. 15, CMP (chemical mechanical polishing) for example may be performed for planarization and to expose the upper surface of semiconductor substrate 1. Contacts 25, 26, 27, 28, and 29 are formed in the above described manner.

In the first embodiment, coating-type resist layer 2, coating-type oxide film 3, and photoresist layer 4 are formed one after another above semiconductor substrate 1. Then, opening 4a is formed through photoresist layer 4. Then, using photoresist layer 4 as a mask, coating-type oxide film 3, coating-type resist layer 2, and semiconductor substrate 1 are etched to form forwardly tapered slopes 2a in coating-type resist layer 2. Coating-type resist layer 2 is subsequently removed to place coating-type oxide film 3 in direct contact with semiconductor substrate 1 and thereby form step portion 6 as illustrated in FIG. 3. A two-step structure may be formed from step portion 6 and coating-type oxide film 3 in the above described manner.

Further in the first embodiment, coating-type resist layer 2, coating-type oxide film 3, and photoresist layer 4 are formed one after another above semiconductor substrate 1 and the existing coating-type oxide film 3. Then, opening 4b is formed through photoresist layer 4. Then, using photoresist layer 4 as a mask, coating-type oxide film 3, coating-type resist layer 2, and semiconductor substrate 1 are etched to form forwardly tapered slopes 2a in coating-type resist layer 2. Coating-type resist layer 2 is subsequently removed to place coating-type oxide film 3 in direct contact with the existing coating-type oxide film 3 disposed above semiconductor substrate 1 and thereby form step portions 7 and 8 as illustrated in FIG. 6. A four-step structure may be formed from step portions 6′, 7, 8 and coating-type oxide film 3 in the above described manner. The stepped structure may be further increased in the unit of two steps by repeating the above described process steps.

Further in the first embodiment, a plurality of steps are formed in semiconductor substrate 1 and coating-type oxide film 3, whereafter coating-type resist layer 10, coating-type oxide film 11, and photoresist layer 12 are formed one after another above semiconductor substrate 1 and coating-type oxide film 3. Then, hole patterns are formed into photoresist layer 12 and using photoresist layer 12 as a mask, coating-type oxide film 11 and coating-type resist layer 10 are etched by RIE without using fluorine gas to form holes 13 to 17 as illustrated in FIG. 11. Thereafter, semiconductor substrate 1 and coating-type oxide film 3 are further etched by RIE using fluorine gas to form contact holes 19 to 23 as illustrated in FIG. 12. It is thus, possible to form patterns having different depths simultaneously while obtaining sufficiently large inner diameters at the lower portions of the patterns. As a result, it is possible to suppress the contact resistance.

The first embodiment also enables formation of a stepped structure having two steps in a single photolithography, i.e. exposure process. It is thus, possible to reduce the manufacturing process steps as well as the manufacturing cost.

### OTHER EMBODIMENTS

The following structures may be employed in addition to the embodiment described above.

Semiconductor substrate 1 comprising silicon for example was used as a workpiece in the embodiment described above. Films such as SiO₂ film or TEOS (tetraethyl orthosilicate) film may be used instead.

Coating-type oxide film 3 was used as the second layer and the twenty first layer in the embodiment described above. Films such as a coating-type silicon film, P-CVD (plasma chemical vapor deposition) oxide film, or ULT (ultra low temperature)-SiO₂ film may be used instead.

In the embodiment described above, it is possible to form patterns having different depths simultaneously while obtaining sufficiently large inner diameters at the lower portions of the patterns.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
forming a first layer comprising an organic film above a work layer;
forming a second layer comprising an inorganic film above the organic film;
forming a third layer above the second layer;
forming an opening pattern into the third layer;
etching the second layer, the first layer, and the work layer using the third layer as a mask, the etching progressing obliquely through the first layer to form a slope in the first layer; and
removing the first layer to cause the second layer to be disposed in direct contact with the work layer to thereby form a step portion.

2. The method according to claim 1, further comprising forming an eleventh layer comprising an organic film above the work layer and the second layer;
forming a twenty first layer comprising an inorganic film above the eleventh layer;
forming a thirty first layer above the twenty first layer;
forming an opening pattern into the thirty first layer;
etching the twenty first layer, the eleventh layer, the second layer, and the work layer using the thirty first layer as a mask, the etching progressing obliquely through the eleventh layer to form a slope in the eleventh layer;
removing the eleventh layer to cause the twenty first layer to be disposed in direct contact with the second layer to thereby form a step portion, and
repeating the forming the eleventh layer to the removing the eleventh layer to form the step portion for a desired number of times.

3. The method according to claim 2, further comprising:
forming a fourth layer comprising an organic film above the work layer, the second layer, and the twenty first layer;
forming a fifth layer comprising an inorganic film above the fourth layer;
forming a sixth layer above the fifth layer;
forming a hole pattern into the sixth layer; and
etching the fifth layer and the fourth layer using the sixth layer as a mask and using the work layer, the second layer, and the twenty first layer as a stopper to simultaneously form patterns having different depths.

4. The method according to claim 2, wherein the first layer and the eleventh layer each comprises a coating-type resist or carbon formed by chemical vapor deposition.

5. The method according to claim 2, wherein the second layer and the twenty first layer each comprises a coating-type silicon, a coating-type silicon oxide film, an oxide film formed by plasma-chemical vapor deposition, or an ultra-low-temperature silicon oxide film.

6. The method according to claim 2, wherein the work layer is a semiconductor substrate comprising silicon, the first layer and the eleventh layer are each formed of a coating-type resist layer comprising a spin on carbon, the second layer and the twenty first layer are each formed of coating-type oxide film comprising a spin on glass, and the third layer and the thirty first layer are each formed of a photoresist layer.

7. The method according to claim 6, wherein the etching progressing obliquely through the first layer and the eleventh layer is carried out by reactive ion etching.

8. The method according to claim 7, wherein the slope formed by the etching progressing obliquely through the first layer and the eleventh layer has an inclination angle ranging from 60 degrees to 84 degrees.

9. The method according to claim 6, wherein removing the first layer and removing the eleventh layer are carried out by dry etching.

10. The method according to claim 9, wherein the dry etching employs a process gas in which oxygen gas occupies approximately 80% or more of total gas content and wherein a temperature of the semiconductor substrate is specified to range from −10 degrees Celsius to 80 degrees Celsius.

11. The method according to claim 10, wherein the process gas is an oxygen gas; a mixture of an oxygen gas and a nitrogen gas; a mixture of an oxygen gas, an argon gas, and a nitrogen gas; or a mixture of an oxygen gas and methane gas.

12. The method according to claim 3, further comprising etching the work layer, the second layer, and the twenty first layer to form a plurality of holes having different depths.

13. The method according to claim 12, wherein the work layer is a semiconductor substrate comprising silicon, the first layer, the eleventh layer, and the fourth layer are each formed of a coating-type resist layer comprising a spin on carbon, the second layer, the twenty first layer, and the fifth layer are each formed of coating-type oxide film comprising a spin on glass, and the third layer, the thirty first layer, and the sixth layer are each formed of a photoresist layer.

14. The method according to claim 13, wherein etching the fifth layer and the fourth layer to simultaneously form patterns having different depths is carried out by reactive ion etching.

15. The method according to claim 14, wherein the process gas used in the RIE primarily comprises an oxygen gas and does not contain a fluorine gas.

16. The method according to claim 13, wherein etching the work layer, the second layer and the twenty first layer to simultaneously form holes having different depths is carried out by reactive ion etching.

17. The method according to claim 16, wherein a process gas used in the reactive ion etching is a mixture of an oxygen gas and a gas primarily comprising a carbon fluoride.

18. A semiconductor device comprising:
a work layer;
a plurality of step portions defined in an upper surface of the work layer;
an inorganic film disposed in an outer side of the plurality of step portions defined in the upper surface of the work layer, the organic film having two step portions defined therein; and
a plurality of holes extending into the plurality of step portions defined in the upper surface of the work layer and the two step portions defined in the inorganic film.

19. The device according to claim 18, wherein the holes are filled with a metal material.

20. The device according to claim 18, wherein the work layer comprises a semiconductor substrate formed of silicon, SiO₂ film, or a tetraethyl orthosilicate film, and wherein the inorganic film comprises a coating-type silicon, a coating-type silicon oxide film, an oxide film formed by plasma-chemical vapor deposition, or an ultra-low-temperature silicon oxide film.
